(19) United States
(12) Patent Application Publication
(10) Pub. No.: US 2025/0239432 A1
(43) Pub. Date: Jul. 24, 2025

(54) ION BEAM PROCESSING SYSTEM

(71) Applicant: Samsung Electronics Co., Ltd., Suwon-si (KR)

(72) Inventors: Backkyu Choi, Suwon-si (KR); Jongsoon Park, Suwon-si (KR); Seungju Park, Suwon-si (KR); Jinwook Lee, Suwon-si (KR)

(21) Appl. No.: 19/013,646

(22) Filed: Jan. 8, 2025

(30) Foreign Application Priority Data
Jan. 19, 2024 (KR) 10-2024-0008999
Mar. 12, 2024 (KR) 10-2024-0034722

(51) Int. Cl. H01J 37/305; H01J 37/08; H01J 37/24; H01J 37/32

(52) U.S. Cl. CPC H01J 37/3053; H01J 37/08; H01J 37/24; H01J 37/32715; H01J 2237/0041

(57) ABSTRACT

Provided is an ion beam processing system including a plasma chamber including extraction opening for extracting an ion beam, an electron beam source unit disposed adjacent to the plasma chamber in a first direction and including an emission opening for emitting an electron beam, a substrate support unit provided to be movable in the first direction and to support a substrate, and a voltage supply unit configured to supply a voltage to the substrate support unit, wherein, when an electron beam emitted from the electron beam source unit is incident on the substrate, the voltage supply unit applies a positive voltage to the substrate support unit.

### CROSS-REFERENCE TO RELATED APPLICATIONS

This application is based on and claims priority under 35 U.S.C. § 119 to Korean Patent Application No. 10-2024-0008999, filed on Jan. 19, 2024, and Korean Patent Application No. 10-2024-0034722, filed on Mar. 12, 2024, in the Korean Intellectual Property Office, the disclosures of both of which are incorporated by reference herein in their entireties.

### BACKGROUND

The inventive concept relates to a plasma processing system, and more particularly, to a processing system using an ion beam.

Semiconductor devices may be manufactured through various processes. For example, a semiconductor device may be manufactured through a photo process, an etching process, a deposition process, etc. on a wafer such as a silicon wafer. During an etching process or a deposition process, an ion beam may be used. An ion beam may be generated from an ion beam source. An ion beam source may extract ions from plasma. To extract ions from plasma, a grid may be used. Ions may be extracted to the outside through holes formed by the grid. An ion beam extracted through the grid may be irradiated to a target or a substrate. Colliding ions strike a surface of a substrate and may remove a material through momentum transfer (or, in the case of reactive ion etching, through reaction).

As semiconductor devices become more highly integrated and wafers become larger, improvements in process precision are demanded. Meanwhile, due to phenomena such as deterioration of an etch rate, which is caused by, as positive ions used as an ion beam enter a wafer, positive charges accumulated on a wafer and preventing additional positive ions from reaching the wafer, and an arcing phenomenon, there are limits in improving the precision and the efficiency of an etching process using ion beams.

### SUMMARY

The inventive concept provides an ion beam processing system capable of performing more precise and efficient substrate processing (etching, etc.) using an ion beam.

In addition, the technical goals to be achieved by the inventive concept are not limited to the technical goals mentioned above, and other technical goals may be clearly understood by one of ordinary skill in the art from the following descriptions.

According to an aspect of the inventive concept, there is provided an ion beam processing system including a plasma chamber including an extraction opening for extracting an ion beam, an electron beam source unit disposed adjacent to the plasma chamber in a first direction and including an emission opening for emitting an electron beam, a substrate support unit provided to be movable in the first direction and to support a substrate, and a voltage supply unit configured to supply a voltage to the substrate support unit, wherein, when an electron beam emitted from the electron beam source unit is incident on the substrate, the voltage supply unit applies a positive voltage to the substrate support unit.

According to another aspect of the inventive concept, there is provided an ion beam processing system including a plasma chamber, an electron beam source unit disposed adjacent to the plasma chamber in a first direction, an electrostatic chuck (ESC) located on a movement path extending in the first direction within a process chamber and provided to support a substrate, and a voltage supply unit configured to supply a voltage to the ESC, wherein the plasma chamber and the electron beam source unit are each disposed in a direction perpendicular to the movement path, and the voltage supply unit determines a sign of a voltage to be supplied to the ESC according to a position of the ESC on the movement path.

According to another aspect of the inventive concept, there is provided an ion beam processing system including a plasma chamber, a first grid located on one surface of the plasma chamber and defining an extraction opening for extracting an ion beam, a second grid located inside the plasma chamber and overlapping the extraction opening in a vertical direction, an electron beam source unit disposed adjacent to the plasma chamber in a first direction and including an emission opening for emitting an electron beam, an electrostatic chuck (ESC) located on a movement path extending in the first direction and provided to support a substrate, and a voltage supply unit having a voltage cycle set to alternate between a first period for applying a negative voltage to the ESC and a second period for applying a positive voltage to the ESC, wherein the extraction opening and the emission opening are each provided to face the movement path.

### BRIEF DESCRIPTION OF THE DRAWINGS

Embodiments of the inventive concept will be more clearly understood from the following detailed description taken in conjunction with the accompanying drawings in which like reference characters refer to like elements throughout. In the drawings:

FIG. 1 is a schematic cross-sectional view of an ion beam processing system according to an example embodiment;

FIG. 2 is a plan view showing an ion beam and an electron beam being incident on a wafer by an ion beam processing system according to an example embodiment;

FIG. 3 is a schematic cross-sectional view of an ion beam processing system according to an example embodiment;

FIG. 4A is a schematic cross-sectional view of an ion beam processing system according to an example embodiment, showing an ion beam being incident on a substrate;

FIG. 4B is a schematic cross-sectional view of an ion beam processing system according to an example embodiment, showing an electron beam being incident on a substrate;

FIG. 5 is a diagram showing an example voltage cycle of a voltage supply unit included in an ion beam processing system according to an example embodiment;

FIG. 6 is a diagram showing the schematic structure of an electron beam source unit included in an ion beam processing system according to an example embodiment; and

FIG. 7 is an example method of manufacturing a semiconductor device according to an example embodiment.

### DETAILED DESCRIPTION OF THE EMBODIMENTS

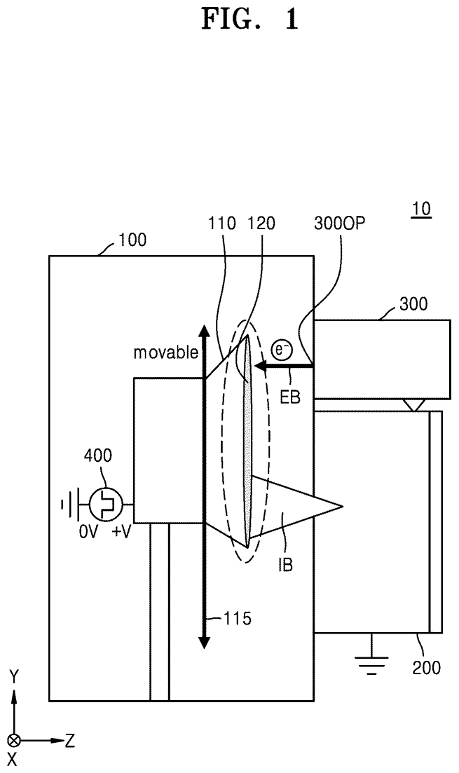

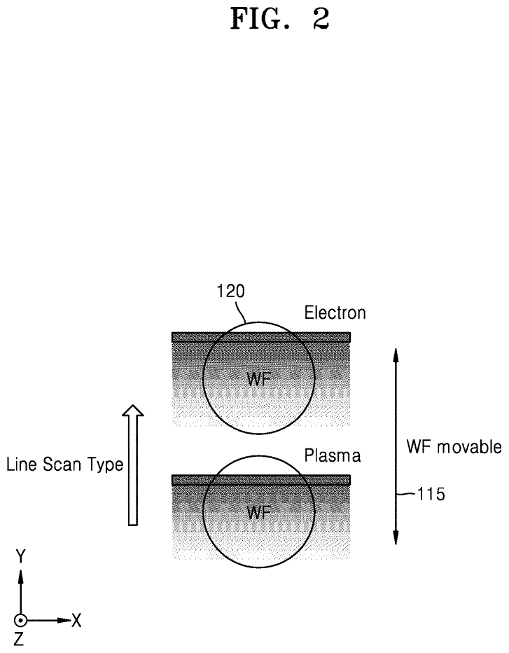

FIG. 1 is a schematic cross-sectional view of an ion beam processing system according to an example embodiment, and FIG. 2 is a plan view showing that an ion beam and an electron beam being incident on a wafer by an ion beam processing system according to an example embodiment.

Referring to FIG. 1, an ion beam processing system 10 according to an embodiment includes a process chamber 100, a plasma chamber 200, and an electron beam source unit 300. The ion beam processing system 10 may be a device that processes a substrate 120 using an etching process in a vacuum environment. The ion beam processing system 10 may process the substrate 120 using a plasma process.

The process chamber 100 houses the substrate 120, and the substrate 120 may be disposed on a substrate support unit 110. The substrate support unit 110 may fix the substrate 120 using electrostatic force or may support the substrate 120 through mechanical clamping. Hereinafter, a method in which the substrate support unit 110 fixes the substrate 120 using electrostatic force will be described as an example.

The substrate support unit 110 may include an electrostatic chuck (ESC) including a base plate (not shown) and a chucking member. The base plate may support the chucking member. According to an embodiment, the base plate may be provided as an aluminum (Al) base plate including aluminum. An electrode is disposed on the chucking member and may support the substrate 120 mounted on the electrode by using electrostatic force generated by a current flowing through the electrode. The chucking member may be installed to be movable in the vertical direction (Z direction) using a driving member within the process chamber 100. When the chucking member is formed to be movable in the vertical direction (Z direction) as described above, the substrate 120 may be positioned in a region that exhibits a more uniform plasma distribution. As described above, the substrate support unit 110 may include a plurality of components, but hereinafter, it may also be understood that the substrate support unit 110 refers to an ESC from among the plurality of components.

The substrate support unit 110 may be moved along a movement path 115 within the process chamber 100. The substrate support unit 110 may be moved to be placed at a particular location on the movement path 115 according to a process. The movement path 115 of the substrate support unit 110 extends in the first direction (Y direction), and the substrate support unit 110 may move in the first direction (Y direction).

A voltage supply unit 400 may supply a voltage to the substrate support unit 110. According to an embodiment, a voltage cycle may be set in the voltage supply unit 400. A voltage cycle of the voltage supply unit 400 may include a period for applying a negative voltage and a period for applying a positive voltage. The voltage supply unit 400 may determine the sign of a voltage to be supplied according to a position of the substrate support unit 110 on the movement path 115.

The voltage supply unit 400 may supply a negative voltage when the substrate support unit 110 is located at a position corresponding to the plasma chamber 200 and supply a positive voltage when the substrate support unit 110 is located at a position corresponding to the electron beam source unit 300. Here, the position corresponding to the plasma chamber 200 may refer to a position on the movement path 115 of the substrate support unit 110 at which the substrate 120 is affected by an ion beam IB extracted from the plasma chamber 200, or an appropriate position for irradiating the ion beam IB to the substrate 120. The position corresponding to the electron beam source unit 300 may refer to a position on the movement path 115 of the substrate support unit 110 at which the substrate 120 is affected by an electron beam EB emitted from the electron beam source unit 300 or an appropriate position for irradiating the electron beam EB to the substrate 120. Detailed descriptions thereof will be given later with reference to FIGS. 2 to 4B.

The plasma chamber 200 may serve as a plasma source for generating plasma. The plasma chamber 200 may be disposed adjacent to the substrate support unit 110 (or the substrate 120) in the vertical direction (Z direction). The ion beam IB extracted from the plasma chamber 200 is irradiated to the substrate 120 adjacent to the plasma chamber 200 in the vertical direction (Z direction), and etching may be performed using the ion beam IB. In this process, space charges on the top of the substrate 120 become positive, and thus it may be difficult for the ion beam IB to reach the substrate 120 as time passes. Therefore, the etch rate may gradually decrease. Also, an arcing phenomenon may occur due to charge accumulation due to incidence of the ion beam IB.

The ion beam processing system 10 according to an embodiment includes the electron beam source unit 300, thereby increasing the etch rate and preventing arcing phenomenon during an etching process using the ion beam (IB).

The electron beam source unit 300 may serve as an electron beam source for generating the electron beam EB that may be irradiated to the substrate 120. The electron beam source unit 300 may be disposed adjacent to the substrate support unit 110 (or the substrate 120) in the vertical direction (Z direction). The electron beam source unit 300 may be disposed adjacent to the plasma chamber 200 in the first direction (Y direction). The electron beam source unit 300 may include an emission opening 300OP for emitting the electron beam EB. The electron beam EB emitted through the emission opening 300OP of the electron beam source unit 300 may reach the substrate 120 and neutralize the positive charges accumulated by the ion beam IE.

Referring to FIG. 1 together with FIG. 2, the substrate support unit 110 may move in the first direction (Y direction) along the movement path 115 during an ion beam processing process according to an embodiment. When the substrate 120 is located at a position corresponding to the plasma chamber 200 according to the movement of the substrate support unit 110, the ion beam IB extracted from the plasma chamber 200 may be incident on the substrate 120 and etching may be performed. Thereafter, the substrate support unit 110 may move in the first direction (Y direction) to position the substrate 120 at a position corresponding to the electron beam source unit 300, and the electron beam EB emitted from the electron beam source unit 300 may be incident on the substrate 120 and neutralize positive charges accumulated on the top surface of the substrate 120.

In other words, as shown in FIG. 2, the ion beam processing process may be performed in the manner of line scanning in the first direction (Y direction), and thus the ion beam IB and the electron beam EB may be sequentially applied to the substrate 120. According to an embodiment, the ion beam IB and the electron beam EB may be alternately incident on the substrate 120.

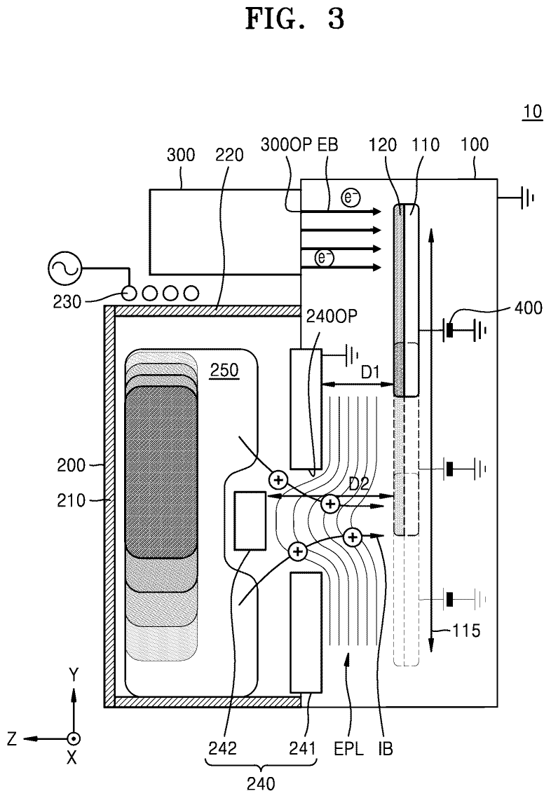

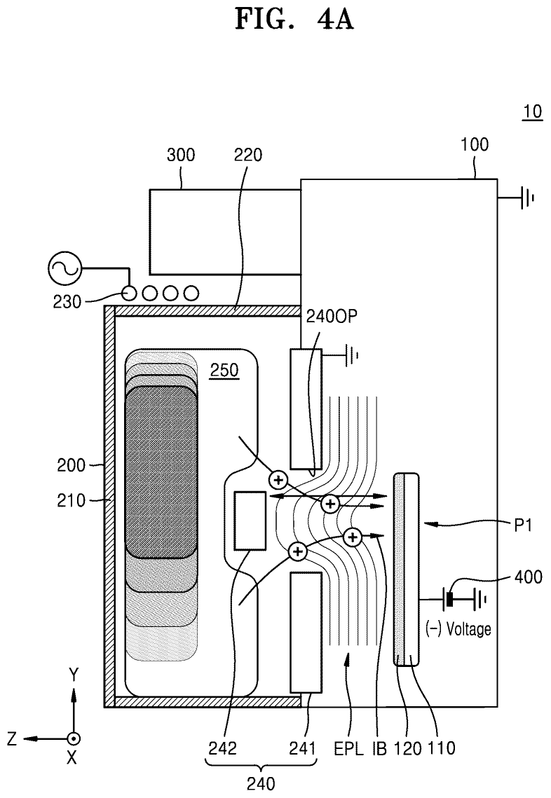

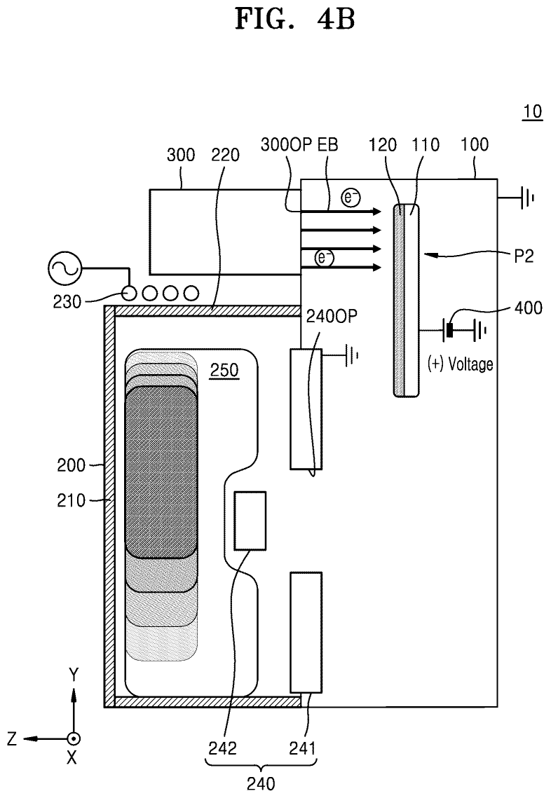

FIG. 3 is a schematic cross-sectional view of an ion beam processing system according to an example embodiment, illustrating each of components of FIG. 1 in detail. FIG. 4A is a schematic cross-sectional view of an ion beam processing system according to an example embodiment, showing that an ion beam incident on a substrate, and FIG. 4B is a schematic cross-sectional view of an ion beam processing system according to an example embodiment, showing that an electron beam is incident on the substrate.

Referring to FIG. 3, the plasma chamber 200 may include a conductive wall 210. The plasma chamber 200 may be based on a certain potential through the conductive wall 210. An RF power generator may be connected to an RF antenna 230 through an impedance matching network to generate plasma 250 in plasma chamber 200. RF power may be transmitted from the RF power generator to gas atoms and/or molecules through the RF antenna 230 and a dielectric window 220. The plasma chamber 200 may function as a plasma source, e.g., an RF inductively coupled plasma (ICP) source, a capacitively coupled plasma (CCP) source, a helicon source, an electron cyclotron resonance (ECR) source, an indirectly heated cathode (IHC) source, a glow discharge source, or some of other plasma sources known to one of ordinary skill in the art.

A gas manifold (not shown) may be connected to the plasma chamber 200 via appropriate gas lines and gas inlets. Other components of the plasma chamber 200 may also be connected to a vacuum system (not shown), e.g., a turbomolecular pump supported by a rotary or membrane pump. The plasma chamber 200 is defined by chamber walls and may be disposed adjacent to the process chamber 100.

According to an embodiment, an extraction unit 240 may be disposed on one surface of the plasma chamber 200. The one surface of the plasma chamber 200 may be a surface adjacent to the substrate 120. For example, the one surface of the plasma chamber 200 may be adjacent to an upper surface of the substrate 120. The extraction unit 240 may be combined with the plasma chamber 200.

According to an embodiment, extraction unit 240 may include a first grid 241 and a second grid 242. The first grid 241 may define an extraction opening 240OP of the plasma chamber 200 and define a space through which ions may pass from the plasma chamber 200. According to an embodiment, the first grid 241 may include a plasma plate defining the extraction opening 240OP. The plasma plate may include an electrical insulator, e.g., Al₂O₃, quartz, AIN or any suitable electrically insulating material. The first grid 241 may further include an extraction electrode formed from a thin-film including an electrically conductive material.

The second grid 242 may be disposed to overlap the extraction opening 240OP in the vertical direction (Z direction). The second grid 242 may be located inside the plasma chamber 200. The second grid 242 may serve to block the ion beam IB from being vertically incident from the plasma chamber 200 to the substrate 120. According to an embodiment, the space between the second grid 242 and the first grid 241 may be defined as a slit through which ions pass.

According to an embodiment, the distance between the first grid 241 and the second grid 242 in the vertical direction (Z direction) may be about 3 mm. The thickness of the first grid 241 in the vertical direction (Z direction) may be about 6.8 mm. The thickness of the second grid 242 in the vertical direction (Z direction) may be about 6 mm.

According to an embodiment, a distance D1 between the first grid 241 and the substrate 120 in the vertical direction (Z direction) may be smaller than a distance D2 between the second grid 242 and the substrate 120 in the vertical direction (Z direction). According to an embodiment, the distance D2 between the second grid 242 and the substrate 120 in the vertical direction (Z direction) may be from about 14.8 mm to about 16.8 mm.

According to an embodiment, in the ion beam processing system 10, the ion beam IB may be bent from the extraction unit 240 through bias power and enter the substrate 120 at a certain angle to perform etching. FIG. 3 shows an equipotential line (EPL) formed by bias power, and the angle of incidence of the ion beam IB may be adjusted by adjusting the magnitude of the bias power. As the ion beam IB enters the substrate 120 at an angle of incidence, more precise processing of the substrate 120 may be performed.

Referring to FIG. 3, as described above, the plasma chamber 200 and the electron beam source unit 300 each may be disposed in a direction perpendicular to the substrate support unit 110 (or the substrate 120) (the vertical direction (Z direction)). The plasma chamber 200 and the electron beam source unit 300 may be arranged side-by-side in the first direction (Y direction). The extraction opening 240OP of the plasma chamber 200 and the emission opening 300OP of the electron beam source unit 300 may be provided to face the top surface of the substrate support unit 110 (or the substrate 120). The extraction opening 240OP of the plasma chamber 200 and the emission opening 300OP of the electron beam source unit 300 may be provided toward the movement path 115 of the substrate support unit 110 (or the substrate 120).

The ion beam processing system 10 may perform etching in the manner of line scanning in the first direction (Y direction). FIG. 3 shows that the substrate support unit 110 and the substrate 120 move in three stages in the +Y direction.

As the substrate support unit 110 (or substrate 120) moves in the +Y direction, the ion beam IB extracted from the plasma chamber 200 and the electron beam EB emitted from the electron beam source unit 300 may be sequentially incident on the substrate 120. Therefore, positive charges accumulated by the ion beam IE may be neutralized to secure the etch rate and to prevent the arcing phenomenon.

According to an embodiment, the voltage supply unit 400 may determine the sign of a voltage to be supplied to the substrate support unit 110 according to the charge of a beam incident on the substrate 120. When the ion beam IB extracted from the plasma chamber 200 is incident on the substrate 120, the voltage supply unit 400 may apply a negative voltage to the substrate support unit 110. When the electron beam EB emitted from the electron beam source unit 300 is incident on the substrate 120, the voltage supply unit 400 may apply a positive voltage to the substrate support unit 110.

When the positively charged ion beam IB is incident on the substrate 120, the voltage supply unit 400 may supply a negative voltage to the substrate support unit 110, thereby helping the ion beam IB to smoothly reach the substrate 120. When the negatively charged electron beam EB is incident on the substrate 120, the voltage supply unit 400 may supply a positive voltage to the substrate support unit 110, thereby helping the electron beam EB to smoothly reach the substrate 120. In other words, since the ion beam processing system 10 according to an embodiment includes the voltage supply unit 400 that supplies a voltage of an appropriate sign (e.g., a positive voltage or a negative voltage) to the substrate support unit 110 during the ion beam processing process, the ion beam processing system 10 may have a structure in which not only the ion beam IB for processes such as etching, but also the electron beam EB for neutralizing positive charges accumulated by the ion beam IB may also effectively reach the substrate 120. Through this structure, ion beam etching and charge neutralization may be performed efficiently.

In other words, the voltage supply unit 400 according to an embodiment may determine the sign of a voltage (e.g., a positive voltage or a negative voltage) to be supplied to the substrate support unit 110 according to the position of the substrate support unit 110 (or the substrate 120) on the movement path 115.

Referring to FIGS. 4A and 4B, the voltage supply unit 400 may apply a negative voltage ((−) voltage) to the substrate support unit 110 at a first position P1 on the movement path 115 corresponding to the plasma chamber 200 and apply a positive voltage ((+) voltage) to the substrate support unit 110 at a second position P2 on the movement path 115 corresponding to the electron beam source unit 300.

According to an embodiment, the first position P1 may be a position at which the substrate 120 is affected by the ion beam IB extracted from the plasma chamber 200 and/or a position at which the substrate 120 overlaps the plasma chamber 200 in the vertical direction (Z direction) and may be an appropriate position for irradiating the ion beam IB to the substrate 120.

According to an embodiment, the second position P2 may be a position at which the substrate 120 is affected by the electron beam EB emitted from the electron beam source unit 300 and/or a position at which the substrate 120 overlaps the electron beam source unit 300 in the vertical direction (Z direction) and may be an appropriate position for irradiating the electron beam EB to the substrate 120.

In other words, when the substrate support unit 110 (or substrate 120) is located at the first position P1 as shown in FIG. 4A, the ion beam IB extracted from the plasma chamber 200 is incident on the substrate 120, and, when the substrate support unit 110 (or substrate 120) is located at the second position P2 as shown in FIG. 4B, the electron beam EB emitted from the electron beam source unit 300 is incident on the substrate 120.

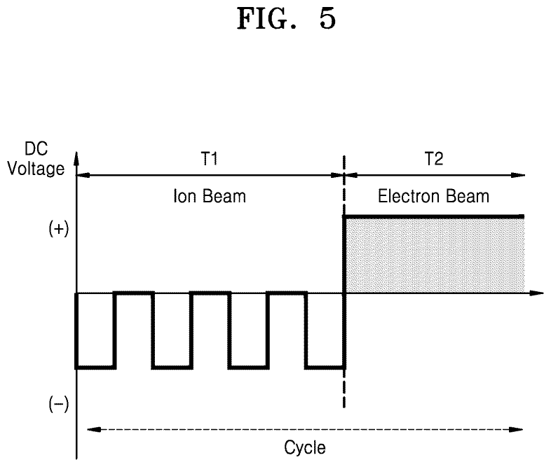

FIG. 5 is a diagram showing an example voltage cycle Cycle of the voltage supply unit 400 included in the ion beam processing system 10 according to an example embodiment.

Referring to FIG. 5 together with FIGS. 3 to 4B, the voltage cycle Cycle of the voltage supply unit 400 includes a first period T1 for supplying a negative voltage to the substrate support unit 110 and a second period T2 for supplying a positive voltage to the substrate support unit 110. The voltage cycle Cycle including the first period T1 and the second period T2 may be set to the voltage supply unit 400. As the first period T1 and the second period T2 alternate by the voltage cycle Cycle, the voltage supply unit 400 may alternately supply a negative voltage and a positive voltage to the substrate support unit 110.

It may be understood that the first period T1 represents a voltage when the substrate support unit 110 (or the substrate 120) is located at the first position P1 and the second period T2 represents a voltage when the substrate support unit 110 (or the substrate 120) is located at the second position P2.

In FIG. 5, the first period T1 illustrates a voltage graph in the form of a pulse, and the second period T2 illustrates a voltage graph in the form of a straight line. However, embodiments are not limited thereto. According to an embodiment, the first period T1 may be set in an appropriate form as needed, such as having a straight voltage rather than a pulse-shaped voltage or a pulse-shaped voltage with a width different from that shown in FIG. 5. Likewise, the second period T2 may also be set to have a pulse-type voltage, unlike the one shown in FIG. 5.

When the ion beam IB is incident on the substrate 120, the etch rate of the first period T1 may be affected thereby according to a voltage set to a voltage supply unit. However, since electrons are very light compared to ions, damage to the substrate 120 caused by the electron beam EB colliding the substrate 120 is subtle. Therefore, the second period T2 may be set to have a certain value or greater value to facilitate the incidence of the electron beam EB on the substrate 120, but the form of a voltage may be freely set.

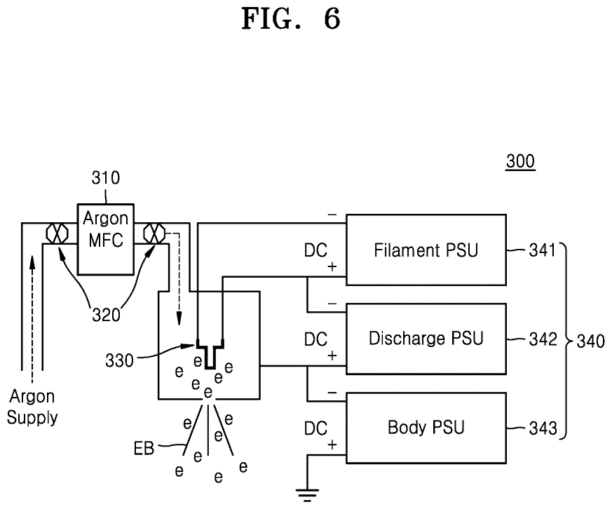

FIG. 6 is a diagram showing the schematic structure of the electron beam source unit 300 included in the ion beam processing system 10 according to an example embodiment.

Referring to FIG. 6, the electron beam source unit 300 includes an argon (Ar) mass flow controller (MFC) 310, pneumatic valves 320, a filament 330, and a power supply 340. The power supply 340 may include a filament power unit 341, a discharge power unit 342, and a body power unit 343. The electron beam source unit 300 may supply Ar to the filament 330 through the Ar MFC 310 and apply a current to the filament 330 through the power supply 340 to raise the temperature of the filament 330 and discharge electrons.

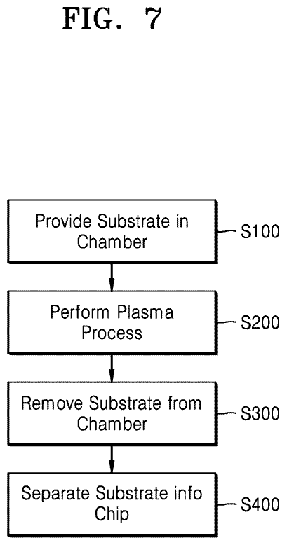

FIG. 7 is a flow chart illustrating a method of manufacturing a semiconductor device according to an example embodiment. Referring to FIG. 7, the manufacturing method includes steps of providing a semiconductor substrate in a process chamber (S100), performing a plasma process on the semiconductor substrate (S200), removing the semiconductor substrate from the plasma chamber (S300), and separating the semiconductor substrate into a plurality of chips (S400). For example, the plasma process may include an etching process, an ashing process, a deposition process, a sputtering process and/or a cleaning process. In example embodiments, during the plasma process, a dielectric layer or a conductor layer may be etched. For example, the dielectric layer or the conductor layer may be patterned by the plasma while a mask layer covers a portion of the dielectric layer or the conductor layer. The mask layer may be formed by a photolithography process, e.g., a double patterning process or a quadruple patterning process.

The process chamber may be a process chamber 100 of a substrate processing apparatus 10 described in the embodiments of the current disclosure. The process chamber may include various features described with reference to FIGS. 1 through 6. The semiconductor substrate may be a bare substrate on which a semiconductor circuit may be formed in later steps of processes. Alternatively, the semiconductor substrate may be a substrate on which a semiconductor circuit is already formed. After removing the semiconductor substrate from the process chamber 100 and/or performing additional processes completing semiconductor circuits on the semiconductor substrate, the semiconductor substrate may be divided into a plurality of semiconductor chips as shown in step S400 of FIG. 7. For example, the semiconductor chips may be packaged to form semiconductor devices.

While the inventive concept has been particularly shown and described with reference to embodiments thereof, it will be understood that various changes in form and details may be made therein without departing from the spirit and scope of the following claims.

What is claimed is:

1. An ion beam processing system comprising:
a plasma chamber comprising an extraction opening for extracting an ion beam;
an electron beam source unit disposed adjacent to the plasma chamber in a first direction and comprising an emission opening for emitting an electron beam;
a substrate support unit provided to be movable in the first direction and to support a substrate; and
a voltage supply unit configured to supply a voltage to the substrate support unit,
wherein, when an electron beam emitted from the electron beam source unit is incident on the substrate, the voltage supply unit applies a positive voltage to the substrate support unit.

2. The ion beam processing system of claim 1, wherein, when an ion beam extracted from the plasma chamber is incident on the substrate, the voltage supply unit applies a negative voltage to the substrate support unit.

3. The ion beam processing system of claim 1, wherein the ion beam and the electron beam are alternately incident on the substrate.

4. The ion beam processing system of claim 1, wherein the extraction opening of the plasma chamber and the emission opening of the electron beam source unit are provided toward a top surface of the substrate support unit.

5. The ion beam processing system of claim 1, wherein the plasma chamber and the electron beam source unit are each disposed in a direction perpendicular to the top surface of the substrate support unit.

6. The ion beam processing system of claim 1, further comprising:
an extraction unit located on one surface of the plasma chamber and comprising a first grid that defines the extraction opening of the plasma chamber and a second grid overlapping the extraction opening in a vertical direction.

7. The ion beam processing system of claim 1, wherein a voltage cycle set to the voltage supply unit comprises a first period for supplying a negative voltage and a second period for supplying a positive voltage.

8. The ion beam processing system of claim 7, wherein the substrate support unit overlaps the plasma chamber in the vertical direction in the first period and the substrate support unit overlaps the electron beam source unit in the vertical direction in the second period.

9. The ion beam processing system of claim 1, wherein the substrate support unit comprises an electrostatic chuck (ESC), and the voltage supply unit supplies a voltage to the ESC.

10. The ion beam processing system of claim 1, wherein the electron beam source unit comprises a filament, an argon mass flow controller (MFC), and a power supply.

11. An ion beam processing system comprising:
a plasma chamber;
an electron beam source unit disposed adjacent to the plasma chamber in a first direction;
an electrostatic chuck (ESC) located on a movement path extending in the first direction within a process chamber and provided to support a substrate; and
a voltage supply unit configured to supply a voltage to the ESC,
wherein the plasma chamber and the electron beam source unit are each disposed in a direction perpendicular to the movement path, and
wherein the voltage supply unit determines a sign of a voltage to be supplied to the ESC according to a position of the ESC on the movement path.

12. The ion beam processing system of claim 11, wherein the voltage supply unit applies a negative voltage to the ESC at a first position on the movement path corresponding to the plasma chamber and applies a positive voltage to the ESC at a second position on the movement path corresponding to the electron beam source unit.

13. The ion beam processing system of claim 12, wherein, when the ESC is positioned at the first position, an ion beam extracted from the plasma chamber is incident on the substrate, and, when the ESC is positioned at the second position, an electron beam emitted from the electron beam source unit is incident on the substrate.

14. The ion beam processing system of claim 12, wherein the first position overlaps the plasma chamber in the vertical direction, and the second position overlaps the electron beam source unit in the vertical direction.

15. The ion beam processing system of claim 11,
wherein the plasma chamber comprises an extraction opening for extracting an ion beam,
wherein the electron beam source unit comprises an emission opening for emitting an electron beam, and
wherein the extraction opening of the plasma chamber and the emission opening of the electron beam source unit are each provided toward the movement path.

16. The ion beam processing system of claim 15, wherein the ion beam and the electron beam are alternately incident on the substrate according to a position of the ESC.

17. The ion beam processing system of claim 15, further comprising:
an extraction unit comprising a first grid defining the extraction opening of the plasma chamber and a second grid overlapping the extraction opening in the vertical direction and defining a slit through which the ion beam passes between the first grid and the second grid.

18. The ion beam processing system of claim 17, wherein a distance between the first grid and the substrate in the vertical direction is smaller than a distance between the second grid and the substrate in the vertical direction.

19. The ion beam processing system of claim 11, wherein the electron beam source unit comprises a filament, an argon mass flow controller (MFC), and a power supply.

20. An ion beam processing system comprising:
a plasma chamber;
a first grid located on one surface of the plasma chamber and defining an extraction opening for extracting an ion beam;
a second grid located inside the plasma chamber and overlapping the extraction opening in a vertical direction;
an electron beam source unit disposed adjacent to the plasma chamber in a first direction and comprising an emission opening for emitting an electron beam;
an electrostatic chuck (ESC) located on a movement path extending in the first direction and provided to support a substrate; and
a voltage supply unit having a voltage cycle set to alternate between a first period for applying a negative voltage to the ESC and a second period for applying a positive voltage to the ESC,
wherein the extraction opening and the emission opening are each provided to face the movement path.
